(19) United States
(12) Patent Application Publication
(10) Pub. No.: US 2026/0282926 A1
(43) Pub. Date: Sep. 17, 2026

(54) Semiconductor Device and Method of Forming AIP Module with Embedded Substrate

(71) Applicant: JCET STATS ChipPAC Korea Limited, Incheon (KR)

(72) Inventors: SeungHyun Lee, Incheon (KR); Yeojun Yun, Incheon (KR); HeeSoo Lee, Incheon (KR)

(73) Assignee: JCET STATS ChipPAC Korea Limited, Incheon (KR)

(21) Appl. No.: 19/079,781

(22) Filed: Mar. 14, 2025

(51) Int. Cl. H01L 23/552; H01L 21/48; H01L 21/56; H01L 23/13; H01L 23/15; H01L 23/31; H01L 23/538; H01L 25/18; H01Q 1/22; H01Q 1/52

(52) U.S. Cl. CPC H10W 42/20; H01Q 1/2283; H01Q 1/526; H10W 70/095; H10W 70/611; H10W 70/65; H10W 70/68; H10W 74/01; H10W 90/00; H10W 90/401; H10W 70/692; H10W 74/111

(57) ABSTRACT

A semiconductor device has a substrate made of glass and a first electrical component disposed within a cavity in the substrate. An interconnect structure is formed over a first surface of the substrate and the first electrical component. An antenna structure is formed over a second surface of the substrate opposite the first surface of the substrate. A conductive via is formed through the substrate between the interconnect substrate and antenna structure. A second electrical component is disposed over the interconnect structure. An encapsulant is deposited over the second electrical component. A shielding layer is disposed over and around the encapsulant. An electrical connector is disposed over the interconnect structure.

### FIELD OF THE INVENTION

The present invention relates in general to semiconductor devices and, more particularly, to a semiconductor device and method of forming an antenna-in-package (AiP) module with an embedded substrate.

### BACKGROUND OF THE INVENTION

Semiconductor devices are commonly found in modern electronic products. Semiconductor devices perform a wide range of functions, such as signal processing, high-speed calculations, transmitting and receiving electromagnetic signals, controlling electronic devices, photo-electric, and creating visual images for television displays. Semiconductor devices are found in the fields of communications, power conversion, networks, computers, entertainment, and consumer products. Semiconductor devices are also found in military applications, aviation, automotive, industrial controllers, and office equipment.

Semiconductor devices, particularly in high frequency applications, such as radio frequency (RF) wireless communications, often contain one or more integrated passive devices (IPDs) to perform necessary electrical functions. Multiple semiconductor die and IPDs can be integrated into a system-in-package (SiP) module for higher density in a small space and extended electrical functionality. Within the SiP module, semiconductor die and IPDs are disposed across a first surface of a substrate for structural support and electrical interconnect. An encapsulant is deposited over the semiconductor die, IPDs, and substrate.

An antenna can be disposed on a second surface of the substrate to provide wireless communication for the SiP module. With the addition of the antenna, the SiP constitutes an AiP. With the semiconductor die and IPDs spread horizontally across the surface of the substrate, no one device can become too large. Otherwise, the semiconductor package may exceed size requirements. Accordingly, present AiP modules limit the size of any one semiconductor device.

### BRIEF DESCRIPTION OF THE DRAWINGS

FIGS. 1a-1f illustrate various semiconductor wafers each with a plurality of semiconductor die separated by a saw street;

FIGS. 2a-2q illustrate a process of forming an AiP module with an embedded substrate without a carrier;

FIGS. 3a-3s illustrate another process of forming an AiP module with an embedded substrate with a carrier; and

FIG. 4 illustrates a printed circuit board (PCB) with different types of packages disposed on a surface of the PCB.

### DETAILED DESCRIPTION OF THE DRAWINGS

The present invention is described in one or more embodiments in the following description with reference to the figures, in which like numerals represent the same or similar elements. While the invention is described in terms of the best mode for achieving the invention's objectives, it will be appreciated by those skilled in the art that it is intended to cover alternatives, modifications, and equivalents as may be included within the spirit and scope of the invention as defined by the appended claims and their equivalents as supported by the following disclosure and drawings. The term “semiconductor die” as used herein refers to both the singular and plural form of the words, and accordingly, can refer to both a single semiconductor device and multiple semiconductor devices.

Semiconductor devices are generally manufactured using two complex manufacturing processes: front-end manufacturing and back-end manufacturing. Front-end manufacturing involves the formation of a plurality of die on the surface of a semiconductor wafer. Each die on the wafer contains active and passive electrical components, which are electrically connected to form functional electrical circuits. Active electrical components, such as transistors and diodes, have the ability to control the flow of electrical current. Passive electrical components, such as capacitors, inductors, and resistors, create a relationship between voltage and current necessary to perform electrical circuit functions.

Back-end manufacturing refers to cutting or singulating the finished wafer into the individual semiconductor die and packaging the semiconductor die for structural support, electrical interconnect, and environmental isolation. To singulate the semiconductor die, the wafer is scored and broken along non-functional regions of the wafer called saw streets or scribes. The wafer is singulated using a laser cutting tool or saw blade. After singulation, the individual semiconductor die are disposed on a package substrate that includes pins or contact pads for interconnection with other system components. Contact pads formed over the semiconductor die are then connected to contact pads within the package. The electrical connections can be made with conductive layers, bumps, stud bumps, conductive paste, or wirebonds. An encapsulant or other molding material is deposited over the package to provide physical support and electrical isolation. The finished package is then inserted into an electrical system and the functionality of the semiconductor device is made available to the other system components.

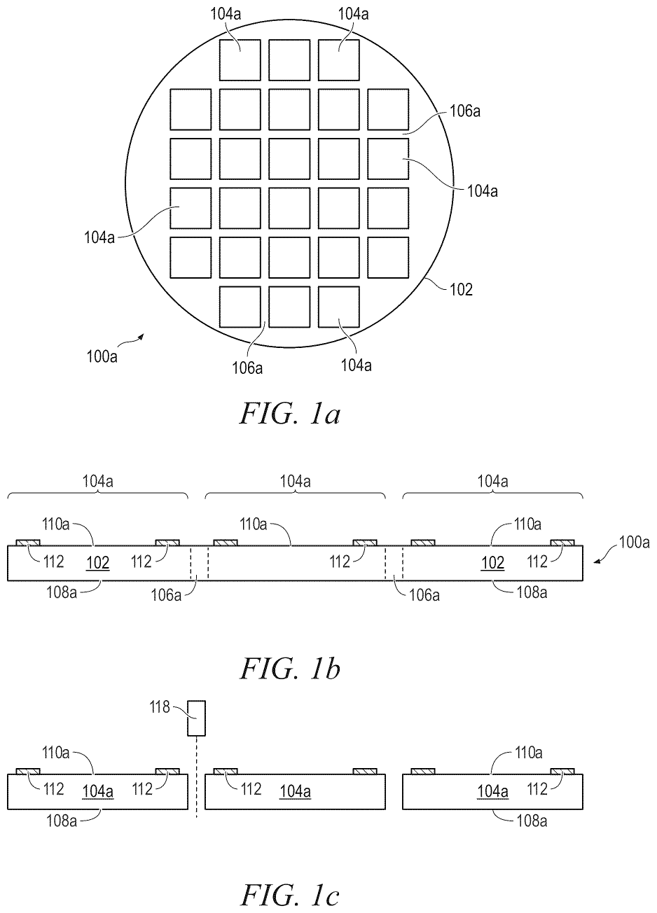

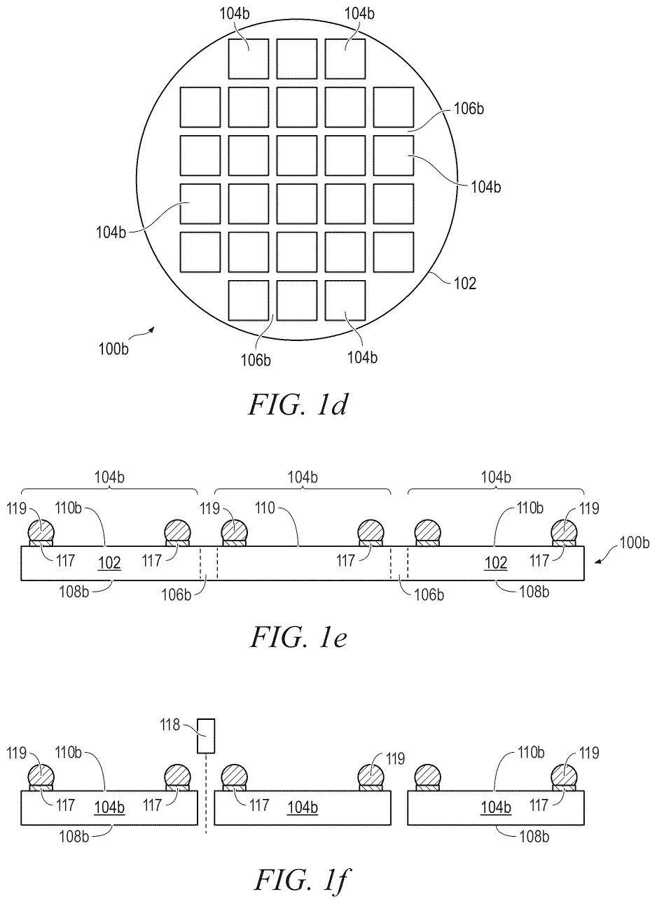

FIG. 1a shows a semiconductor wafer 100a with a base substrate material 102, such as silicon, germanium, aluminum phosphide, aluminum arsenide, gallium arsenide, gallium nitride, indium phosphide, silicon carbide, or other bulk material for structural support. A plurality of semiconductor die or components 104a is formed on wafer 100a separated by a non-active, inter-die wafer area or saw street 106a. Saw street 106a provides cutting areas to singulate semiconductor wafer 100a into individual semiconductor die 104a. In one embodiment, semiconductor wafer 100 a has a width or diameter of 100-450 millimeters (mm).

FIG. 1b shows a cross-sectional view of a portion of semiconductor wafer 100a. In one embodiment, each semiconductor die 104a has a non-active back surface 108a and active surface 110a each containing analog or digital circuits implemented as active devices, passive devices, conductive layers, and dielectric layers formed within the die and electrically interconnected according to the electrical design and function of the die. For example, the circuit may include one or more transistors, diodes, and other circuit elements formed within active surface 110a to implement analog circuits or digital circuits, such as digital signal processor (DSP), application specific integrated circuits (ASIC), memory, or other signal processing circuits. Semiconductor die 104a may also contain IPDs, such as inductors, capacitors, and resistors, for RF signal processing. Semiconductor die 104a can process RF signals transmitted and received through an antenna. In one embodiment, semiconductor die 104a is an RFIC, a monolithic microwave integrated circuit (MMIC), power management integrated circuit (PMIC), or system-on-chip (SoC) type die.

An electrically conductive layer 112 is formed over active surface 110a using PVD, CVD, electrolytic plating, electroless plating process, or other suitable metal deposition process. Conductive layer 112 can be one or more layers of aluminum (Al), copper (Cu), tin (Sn), nickel (Ni), gold (Au), silver (Ag), or other suitable electrically conductive material. Conductive layer 112 operates as contact pads electrically connected to the circuits on active surface 110a.

In FIG. 1c, semiconductor wafer 100a is singulated through saw street 106a using a saw blade or laser cutting tool 118 into individual semiconductor die 104a. The individual semiconductor die 104a can be inspected and electrically tested for identification of known good die or unit (KGD/KGU) post singulation.

Other types of semiconductor die can be made using a wafer 100b, similar to semiconductor wafer 100a. FIG. 1d shows a semiconductor wafer 100b with a base substrate material 102, such as silicon, germanium, aluminum phosphide, aluminum arsenide, gallium arsenide, gallium nitride, indium phosphide, silicon carbide, or other bulk material for structural support. A plurality of semiconductor die or components 104b is formed on wafer 100b separated by a non-active, inter-die wafer area or saw street 106b. Saw street 106b provides cutting areas to singulate semiconductor wafer 100b into individual semiconductor die 104b. In one embodiment, semiconductor wafer 100b has a width or diameter of 100-450 mm.

FIG. 1e shows semiconductor die 104b each having a back or non-active surface 108b and active surface 110b containing analog or digital circuits implemented as active devices, passive devices, conductive layers, and dielectric layers formed within the die and electrically interconnected according to the electrical design and function of the die. Components having a similar function are assigned the same reference number. The circuit may include one or more transistors, diodes, and other circuit elements formed within active surface 110b to implement analog circuits or digital circuits, such as DSP, ASIC, memory, or other signal processing circuit. Semiconductor die 104b may also contain IPDs, such as inductors, capacitors, and resistors, for RF signal processing.

An electrically conductive layer 117 is formed over active surface 110b using PVD, CVD, electrolytic plating, electroless plating process, or other suitable metal deposition process. Conductive layer 117 can be one or more layers of Al, Cu, Sn, Ni, Au, Ag, or other suitable electrically conductive material. Conductive layer 117 operates as contact pads electrically connected to the circuits on active surface 110a.

An electrically conductive bump material is deposited over conductive layer 117 using an evaporation, electrolytic plating, electroless plating, ball drop, or screen printing process. The bump material can be Al, Sn, Ni, Au, Ag, Pb, Bi, Cu, solder, and combinations thereof, with an optional flux solution. For example, the bump material can be eutectic Sn/Pb, high-lead solder, or lead-free solder. The bump material is bonded to conductive layer 117 using a suitable attachment or bonding process. In one embodiment, the bump material is reflowed by heating the material above its melting point to form balls or bumps 119. In one embodiment, bump 119 is formed over an under bump metallization (UBM) having a wetting layer, barrier layer, and adhesive layer. Bump 119 can also be compression bonded or thermocompression bonded to conductive layer 117. Bump 119 represents one type of interconnect structure that can be formed over conductive layer 117. The interconnect structure can also use bond wires, conductive paste, stud bump, micro bump, or other electrical interconnect.

In FIG. 1f, semiconductor wafer 100b is singulated through saw street 106b using a saw blade or laser cutting tool 118 into individual semiconductor die 104b, i.e., with bumps 119. The individual semiconductor die 104b can be inspected and electrically tested for identification of KGD/KGU post singulation.

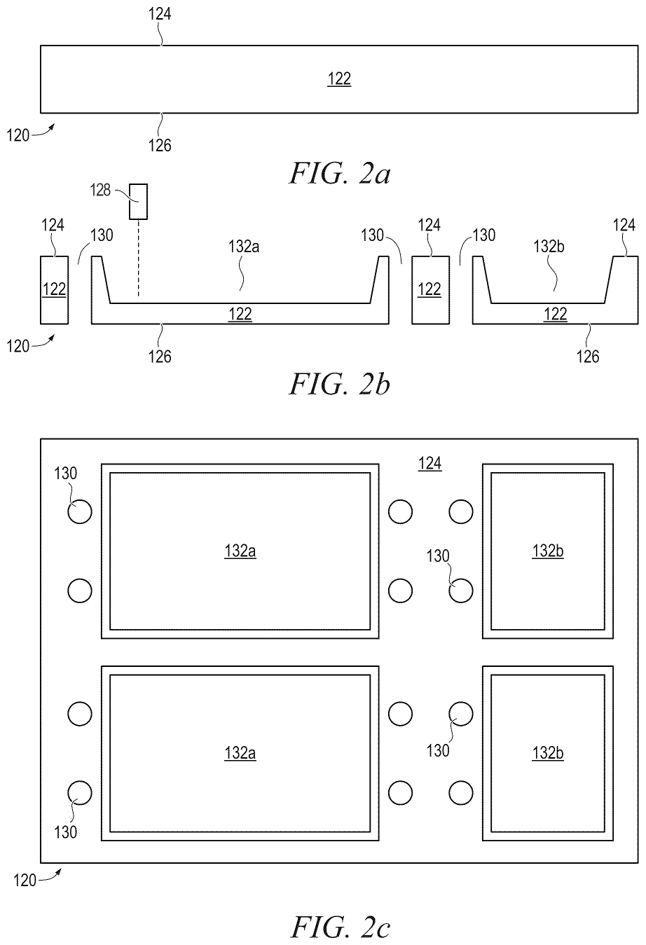

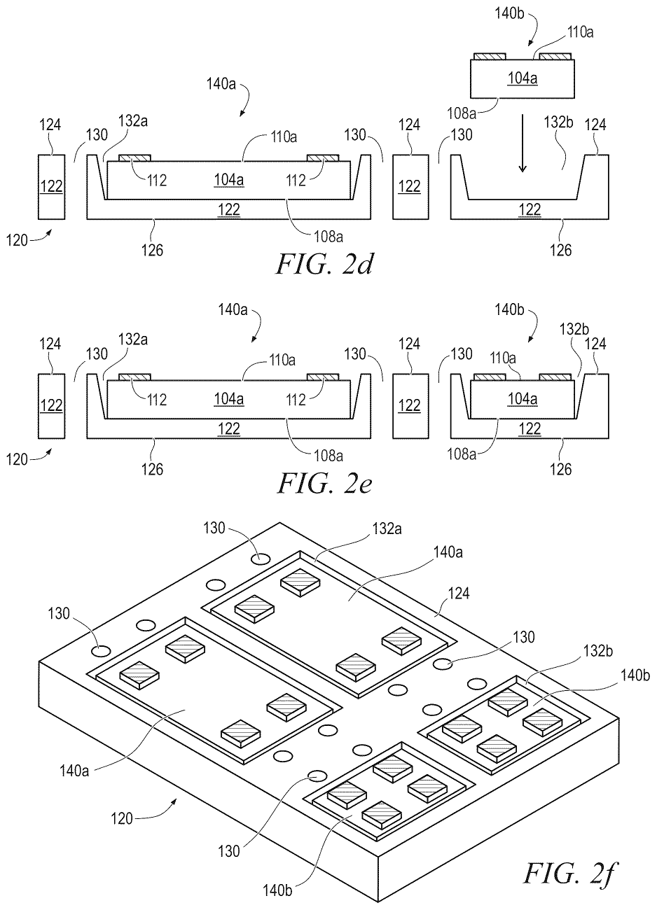

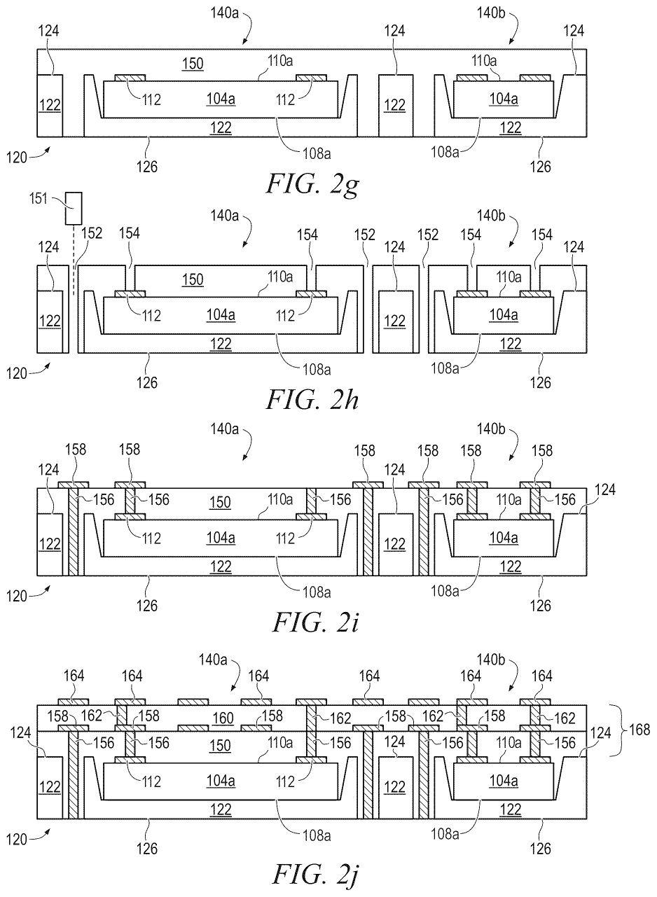

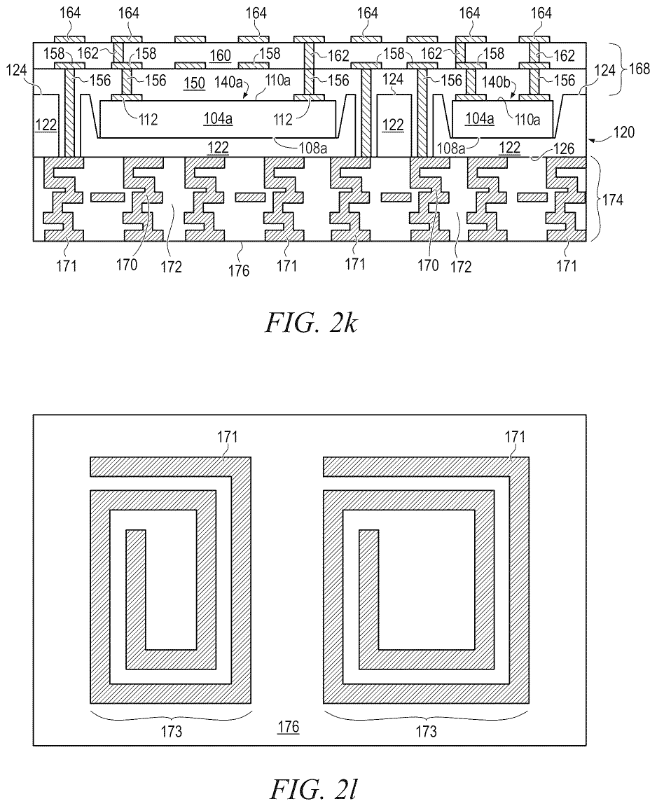

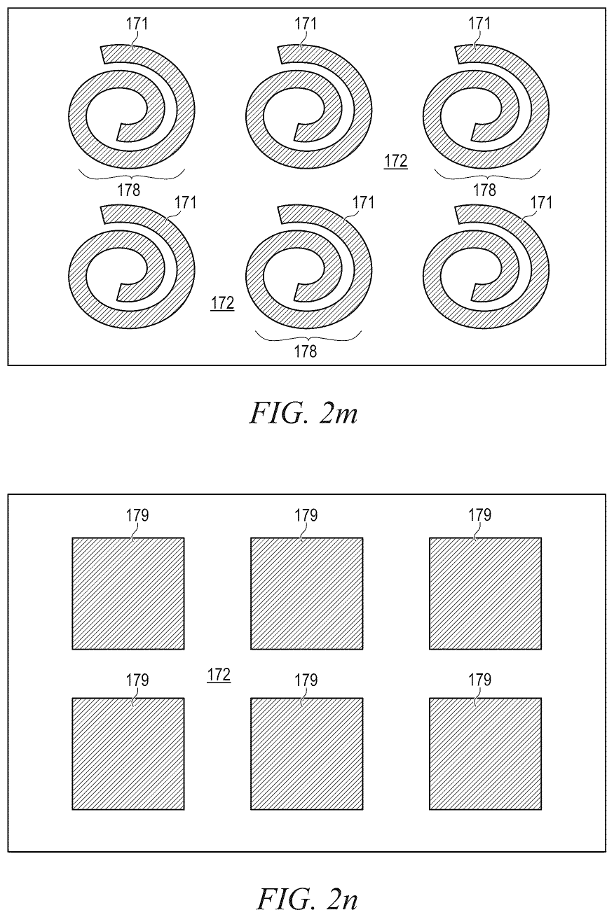

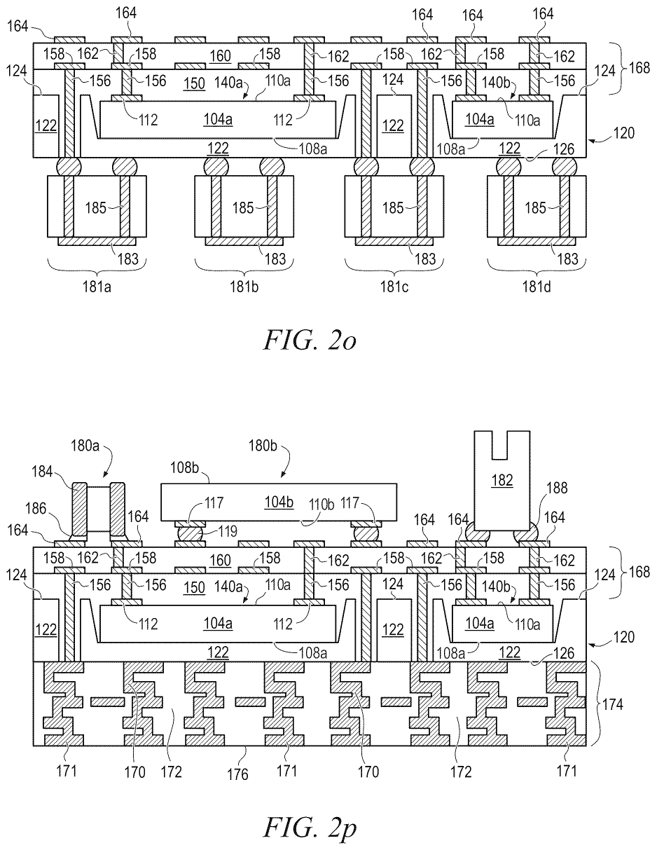

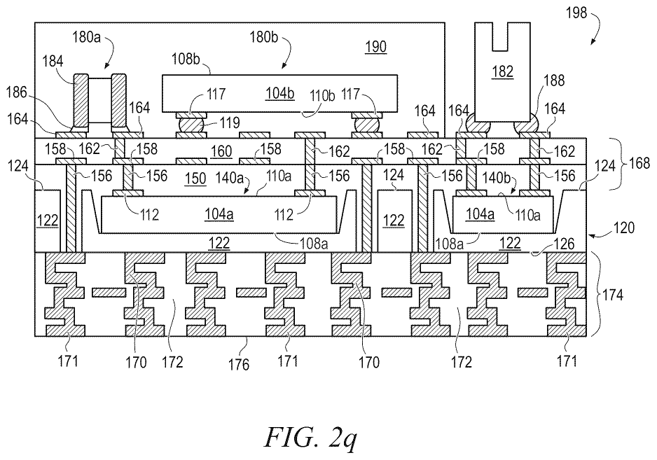

FIGS. 2a-2q illustrate a process of forming an AiP module having an embedded substrate without using a carrier. FIG. 2a shows a cross-sectional view of substrate 120 including core material 122, such as silicon, germanium, aluminum phosphide, aluminum arsenide, gallium arsenide, gallium nitride, indium phosphide, silicon carbide, or other bulk material for structural support. Alternatively, core material 122 can be a multi-layer flexible laminate, ceramic, CCL, or epoxy molding compound. Core material 122 may contain one or more layers of silicon dioxide (SiO2), silicon nitride (Si3N4), silicon oxynitride (SiON), tantalum pentoxide (Ta2O5), aluminum oxide (Al2O3), solder resist, polyimide, benzocyclobutene (BCB), polybenzoxazoles (PBO), and other material having similar insulating and structural properties. Preferably, core material 122 is glass. Substrate 120 has a major surface 124 and major surface 126 opposite surface 124.

In FIG. 2b, a portion of core material 122 is removed by an etching process or laser direct ablation (LDA) using laser 128 to form open vias 130 and die openings or cavities 132a and 132b into surface 124. In the case of core material being glass, a through glass via (TGV) can be applied. In TGV, a laser is applied to make a hole and then etching is applied with hydrofluoric acid (HF). TGV makes the via wider and fully formed during etching. Die openings 132a-132b provide die mounting sites. FIG. 2c is a top view of substrate 120 with open vias 130 and die openings 132a and 132b.

In FIG. 2d, electrical components 140a and 140b are positioned over substrate 120 using a pick and place operation. For example, electrical component 140a can be similar to semiconductor die 104a from FIG. 1c with back surface 108a oriented toward die opening 132a. Likewise, electrical component 140b can be similar to semiconductor die 104a from FIG. 1c, albeit with a different function and form-factor, with back surface 108a oriented toward die opening 132b. In one embodiment, electrical component 140a is an RFIC and electrical component 140b is a PMIC controlling certain operations and functions of electrical component 140a. Alternatively, electrical components 140a and 140b can include other semiconductor die, semiconductor packages, surface mount devices, discrete electrical devices, or IPDs. Electrical components 140a-140b can be attached to a bottom surface of die openings 132a-132b with a die attach film. FIG. 2e shows electrical component 140a disposed within die opening 132a and electrical component 140b disposed within die opening 132b. FIG. 2f is a perspective view of electrical components 140a disposed within die openings 132a and electrical components 140b disposed within die openings 132b. In another embodiment, electrical components 140a and electrical components 140b are disposed over surface 124 of substrate 120, i.e., with no cavities 132a-132b.

In FIG. 2g, insulating layer 150 is formed over surface 124 and into open vias 130 and die openings 132a-132b around electrical components 140a-140b using PVD, CVD, printing, lamination, spin coating, spray coating, sintering or thermal oxidation. Insulating layer 150 contains one or more layers of SiO2, Si3N4, SiON, Ta2O5, Al2O3, solder resist, polyimide, BCB, PBO, and other material having similar insulating and structural properties.

In FIG. 2h, a portion of insulating layer 150 is removed using an etching process or LDA with laser 151 to form openings 152 extending through insulation-filled vias 130 to surface 126 and further form openings 154 extending down to expose conductive layer 112. Note that the width of openings 152 is less than the original open vias 130 as a portion of insulating layer 150 remains on the sidewalls of the vias 130.

In FIG. 2i, an electrically conductive material is formed within openings 152 and 154 using PVD, CVD, electrolytic plating, electroless plating process, or other suitable metal deposition process to form conductive vias 156. Conductive vias 156 can be one or more layers of Al, Cu, Sn, Ni, Au, Ag, or other suitable electrically conductive material. Conductive vias 156 extend vertically through insulating layer 150 to surface 126 and further to electrically connect to conductive layer 112 of electrical components 140a-140b.

An electrically conductive layer 158 is formed over insulating layer 150 and conductive vias 156 using PVD, CVD, electrolytic plating, electroless plating process, or other suitable metal deposition process. Conductive layer 158 can be one or more layers of Al, Cu, Sn, Ni, Au, Ag, or other suitable electrically conductive material. Conductive layer 158 is electrically connected to conductive vias 156 and provides horizontal electrical interconnect across the substrate, such as a redistribution layer (RDL).

In FIG. 2j, insulating layer 160 is formed over insulating layer 150 and conductive layer 158 using PVD, CVD, printing, lamination, spin coating, spray coating, sintering or thermal oxidation. Insulating layer 160 contains one or more layers of SiO2, Si3N4, SiON, Ta2O5, Al2O3, solder resist, polyimide, BCB, PBO, and other material having similar insulating and structural properties. A portion of insulating layer 160 is removed using an etching process or LDA to form openings 152 extending through insulating layer 160 to conductive layer 158 and conductive vias 156. An electrically conductive material is formed within the openings in insulating layer 160 using PVD, CVD, electrolytic plating, electroless plating process, or other suitable metal deposition process to form conductive vias 162. Conductive vias 162 can be one or more layers of Al, Cu, Sn, Ni, Au, Ag, or other suitable electrically conductive material. Conductive vias 162 extend vertically through insulating layer 160 and electrically connect to conductive layer 158 and conductive vias 156.

An electrically conductive layer 164 is formed over insulating layer 160 and conductive vias 162 using PVD, CVD, electrolytic plating, electroless plating process, or other suitable metal deposition process. Conductive layer 164 can be one or more layers of Al, Cu, Sn, Ni, Au, Ag, or other suitable electrically conductive material. Conductive layer 164 is electrically connected to conductive vias 162 and provides horizontal electrical interconnect across the substrate, such as an RDL. Portions of conductive layers 158 and 164 and conductive vias 156 and 162 can be electrically common or electrically isolated depending on the design and function of electrical components 140a-140b and other electrical components. The combination of conductive layers 158 and 164 and conductive vias 156 and 162, and insulating layers 150 and 160 constitute upper interconnect structure 168 formed over surface 124 of substrate 120 and electrical components 140a-140b.

In FIG. 2k, lower interconnect and antenna structure 174 is formed over surface 126 of substrate 120. Lower interconnect and antenna structure 174 includes one or more conductive layers 170 and one or more insulating layers 172. Conductive layers 170 can be one or more layers of Al, Cu, Sn, Ni, Au, Ag, or other suitable electrically conductive material. Conductive layers 170 can be formed using PVD, CVD, electrolytic plating, electroless plating process, or other suitable metal deposition process. Conductive layers 170 provide horizontal electrical interconnect (such as RDL) and vertical electrical interconnect. Portions of conductive layers 170 can be electrically common or electrically isolated depending on the design and function of electrical components 140a and 140b and other electrical components. Insulating layers 172 contain one or more layers of SiO2, Si3N4, SiON, Ta2O5, Al2O3, solder resist, polyimide, BCB, PBO, and other material having similar insulating and structural properties. Insulating layers 172 can be formed using PVD, CVD, printing, lamination, spin coating, spray coating, sintering or thermal oxidation. Insulating layers 172 provide isolation between conductive layers 170. There can be multiple conductive layers like 170 separated by insulating layers 172. Note that conductive vias 156 extend from upper interconnect structure 168 through substrate 120 to electrically connect to conductive layer 170, providing electrical connectivity between upper interconnect structure 168 and lower interconnect and antenna structure 174. Conductive vias 156 provide short vertical interconnects from embedded electrical components 140a-140b to antennas 171 and surface assembled electrical components 180a-180b, see FIG. 2l-2p. The combination of upper interconnect structure 168 and lower interconnect and antenna structure 174 provides double-sided electrical connectivity, including double-sided RDL.

A conductive layer 171 is formed on surface 176 of lower interconnect and antenna structure 174 and electrically connected to conductive layer 170. Conductive layer 171 includes an array of islands 173 of wound or spiral conductive material suitable to provide transmission and reception of RF signals, i.e., an RF antenna, as shown in FIG. 2l. Alternatively, conductive layer 171 includes an array of islands 178 of wound or spiral conductive material suitable to provide transmission and reception of RF signals, i.e., an RF antenna, as shown in FIG. 2m. In yet another embodiment, conductive layer 171 can be formed as a plurality of patch antenna 179, as shown in FIG. 2n. In particular, antenna islands 173 and 178 and antenna patches 179 of conductive layer 171 are exposed from surface 176 to improve RF transmission and reception performance and quality.

In another embodiment, a plurality of discrete antenna modules 181a-181d are disposed over surface 126, as shown in FIG. 2o. Patch antenna 183 are formed on a surface of discrete antenna modules 181a-181d opposite surface 126. Patch antenna 183 are electrically connected to interconnect structure 168 by way of conductive vias 185 and conductive vias 156 and other interconnect structures through substrate 120.

In FIG. 2p, continuing from FIG. 2k, electrical components 180a and 180b are positioned over upper interconnect structure 168 using a pick and place operation, similar to FIGS. 2d-2e. For example, electrical component 180a can be a discrete electrical device, such as a resistor, capacitor, inductor, diode, or transistor. Terminals 184 of electrical component 180a are bonded to conductive layer 164 with conductive paste 186. Electrical component 180b can be similar to semiconductor die 104b from FIG. 1f with active surface 110a oriented toward upper interconnect structure 168. Alternatively, electrical component 180b can include other semiconductor die, semiconductor packages, surface mount devices, discrete electrical devices, or IPDs. Electrical connector 182 is also bonded to electrically connect to conductive layer 164 with bumps 188.

In FIG. 2q, an encapsulant or molding compound 190 is deposited over and around electrical components 180a-180b using a paste printing, compressive molding, transfer molding, liquid encapsulant molding, vacuum lamination, spin coating, or other suitable applicator. Encapsulant 190 can be polymer composite material, such as epoxy resin with filler, epoxy acrylate with filler, or polymer with proper filler. Encapsulant 190 is non-conductive, provides structural support, and environmentally protects the semiconductor device from external elements and contaminants. The combination of embedded substrate 120, electrical components 140a-140b, upper interconnect structure 168, lower interconnect and antenna structure 174, electrical components 180a-180b, and electrical connector 182 constitute AiP module 198.

FIG. 2q represents AiP module 198 with an embedded glass substrate 120. Electrical components 140a-140b are disposed within a cavity of the embedded glass substrate. An electrical interconnect structure 168 is formed on one side of the glass substrate and an interconnect and antenna structure 174 is formed on the opposite side of the glass substrate. Encapsulant can be deposited over electrical components 180a-180b. AiP module 198 provides improved performance with low-loss thin-film dielectrics, high-precision interconnects with seamless transitions, and short vertical interconnects from embedded electrical components to antennas and surface assembled components. AiP module 198 has lower form factor with 100-200 mm thick core, providing shrinkage in the Z-direction. Double-side RDL and passive device integration reduces the number of metal layers. AiP module 198 involves lower cost with large-area panel manufacturing and double-side panel-level fabrication and assembly.

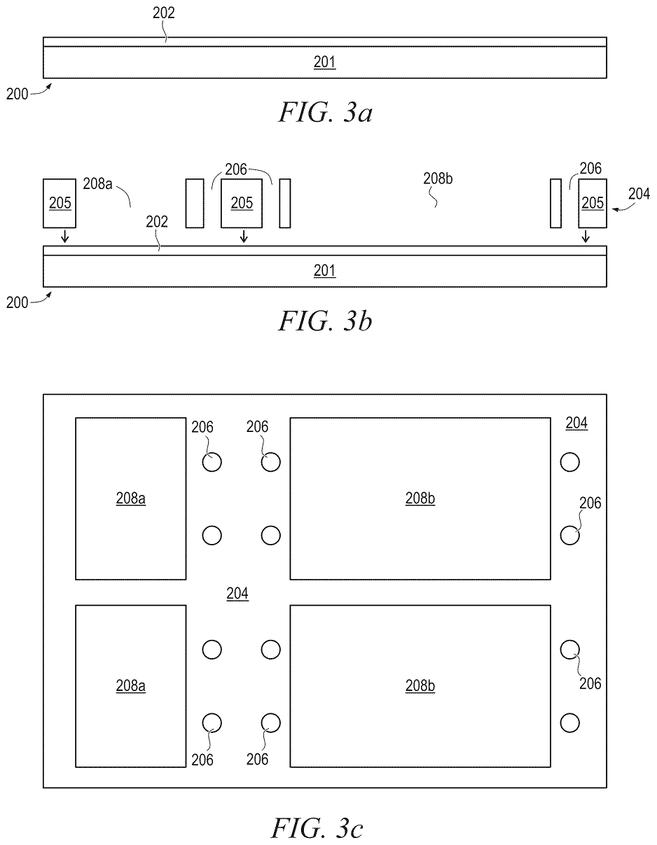

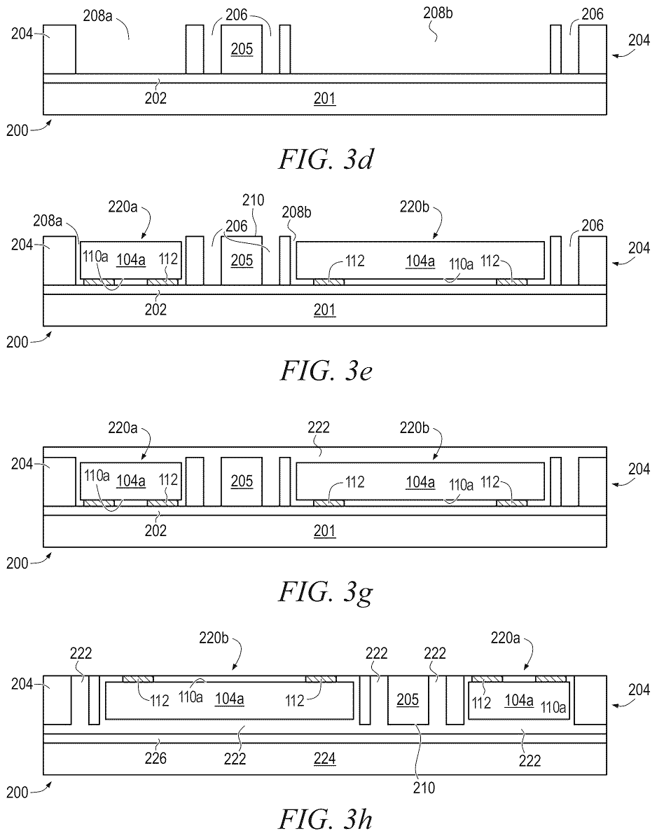

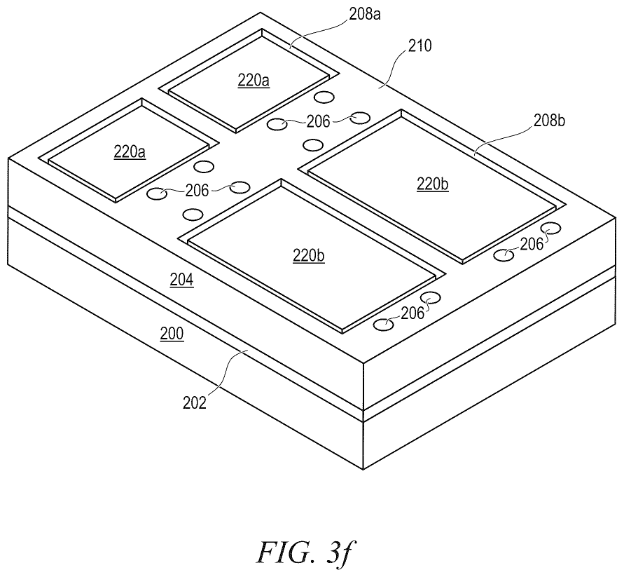

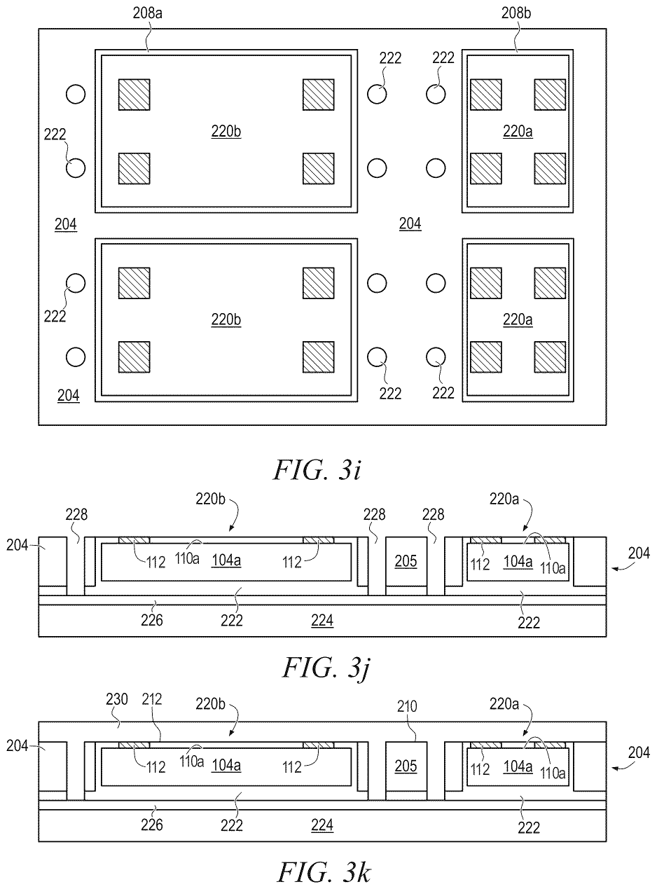

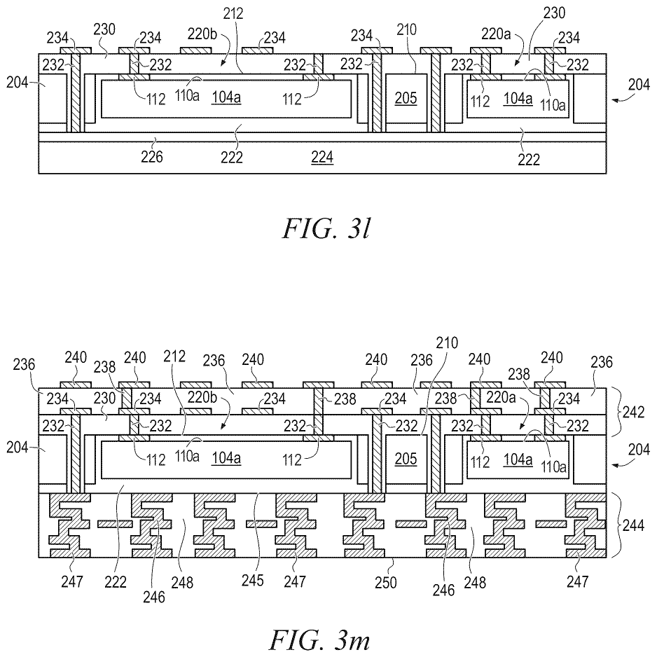

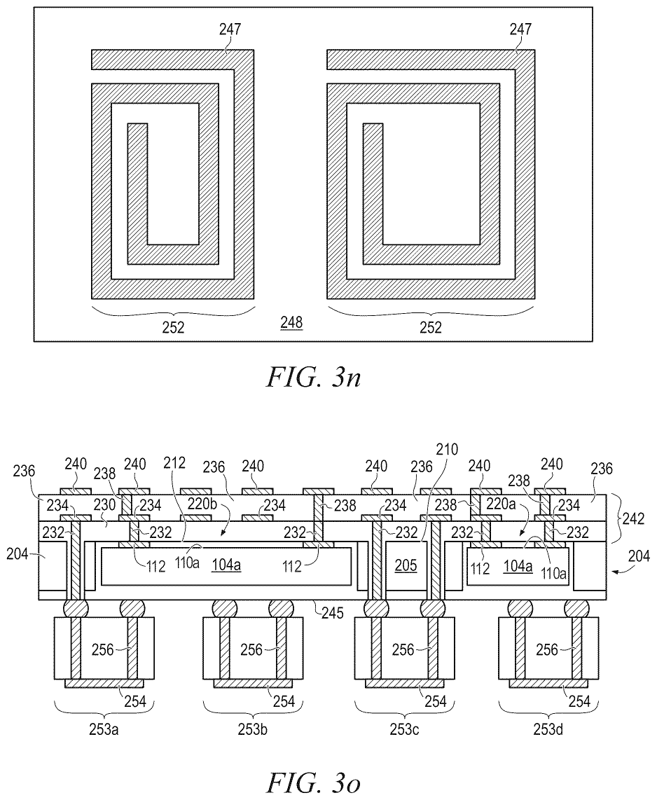

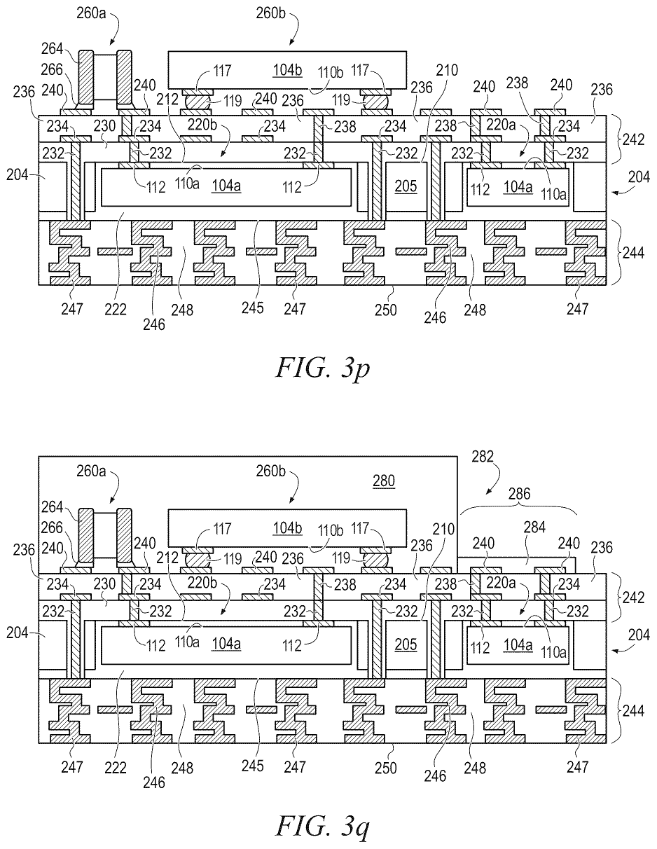

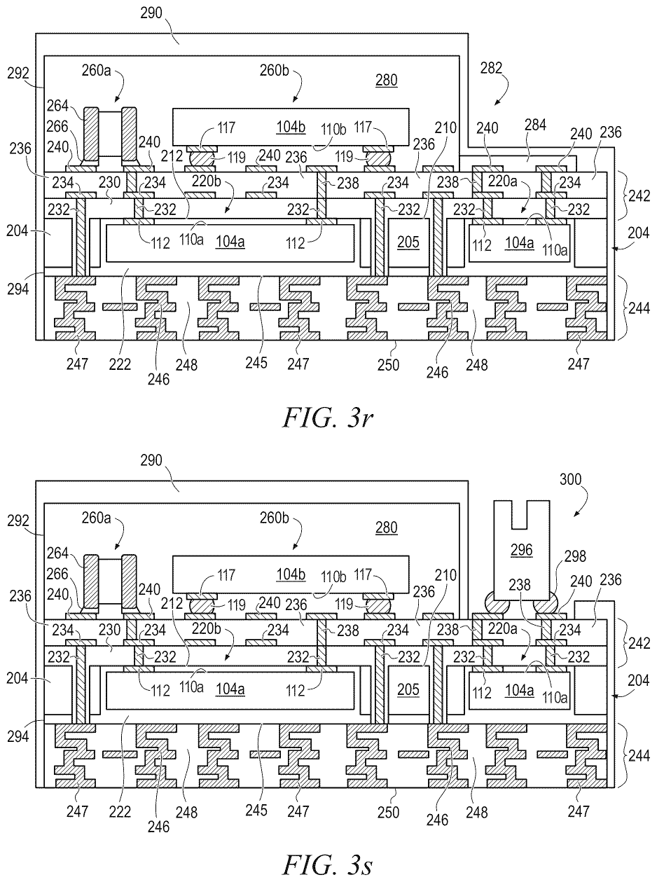

FIGS. 3a-3s illustrate another process of forming an AiP module having an embedded substrate using a carrier. FIG. 3a shows a cross-sectional view of temporary substrate or carrier 200 including core material 201, such as silicon, germanium, aluminum phosphide, aluminum arsenide, gallium arsenide, gallium nitride, indium phosphide, silicon carbide, or other bulk material for structural support. Alternatively, core material 201 can be a multi-layer flexible laminate, ceramic, CCL, or epoxy molding compound. Core material 201 may contain one or more layers of SiO2, Si3N4, SiON, Ta2O5, Al2O3, solder resist, polyimide, BCB, PBO, and other material having similar insulating and structural properties. An adhesive or bonding layer 202 is formed over substrate 200.

In FIG. 3b, substrate 204 is disposed over substrate 200. Substrate 204 includes core material 205, such as silicon, germanium, aluminum phosphide, aluminum arsenide, gallium arsenide, gallium nitride, indium phosphide, silicon carbide, or other bulk material for structural support. Alternatively, core material 205 can be a multi-layer flexible laminate, ceramic, CCL, or epoxy molding compound. Core material 205 may contain one or more layers of SiO2, Si3N4, SiON, Ta2O5, Al2O3, solder resist, polyimide, BCB, PBO, and other material having similar insulating and structural properties. Preferably, core material 205 in substrate 204 is glass.

A portion of core material 204 is removed by an etching process or LDA, similar to FIG. 2b, to form open vias 206 and die openings 208a and 208b extending through the substrate. Die openings 208a-208b provide die mounting areas. FIG. 3c is a top view of substrate 204 with open vias 206 and die openings 208a and 208b.

FIG. 3d shows substrate 204 bonded to substrate 200 with adhesive layer 202. In FIG. 3e, electrical components 220a and 220b are positioned over substrate 204 using a pick and place operation, similar to FIGS. 2d-2e. For example, electrical component 220a can be similar to semiconductor die 104a from FIG. 1c with back surface 108a oriented toward die opening 208a. Likewise, electrical component 220b can be similar to semiconductor die 104a from FIG. 1c, albeit with a different function and form-factor, with back surface 108a oriented toward die opening 208b. In one embodiment, electrical component 220a is an RFIC and electrical component 220b is a PMIC controlling certain operations and functions of electrical component 220a. Alternatively, electrical components 220a and 220b can include other semiconductor die, semiconductor packages, surface mount devices, discrete electrical devices, or IPDs. Electrical components 220a-220b can be attached to adhesive layer 202. FIG. 3e shows electrical component 220a disposed within die opening 208a and electrical component 220b disposed within die opening 208b. FIG. 3f is a perspective view of electrical components 220a disposed within die openings 208a and electrical components 220b disposed within die openings 208b.

In FIG. 3g, encapsulant or molding compound 222 is deposited over and around substrate 204, open vias 206, die openings 208a-208b, and electrical components 220a-220b using a paste printing, compressive molding, transfer molding, liquid encapsulant molding, vacuum lamination, spin coating, or other suitable applicator. Encapsulant 222 can be polymer composite material, such as epoxy resin with filler, epoxy acrylate with filler, or polymer with proper filler. Encapsulant 222 is non-conductive, provides structural support, and environmentally protects the semiconductor device from external elements and contaminants.

In FIG. 3h, temporary substrate or carrier 224 with adhesive layer 226, similar to substrate 200, is bonded to encapsulant 222. Temporary substrate 200 and adhesive layer 202 is then removed by chemical etching, chemical mechanical polishing (CMP), mechanical peel-off, mechanical grinding, thermal bake, ultra-violet (UV) light, or wet stripping to expose conductive layer 112 of electrical components 220a-220b. The assembly is inverted to have substrate 224 on the bottom and conductive layer 112 oriented upward. FIG. 3i is a top view of electrical components 220a-200b disposed within die openings 208a-208b of substrate 204 and covered by encapsulant 222 with conductive layer 112 exposed from the encapsulant.

In FIG. 3j, a portion of encapsulant 222 is removed from vias 206, and possibly a portion of core material 205, using an etching process or LDA, leaving openings 228. In FIG. 3k, insulating layer 230 is formed over surface 210 of substrate 204 and surface 212 of encapsulant 222 and into openings 228 using PVD, CVD, printing, lamination, spin coating, spray coating, sintering or thermal oxidation. Insulating layer 230 contains one or more layers of SiO2, Si3N4, SiON, Ta2O5, Al2O3, solder resist, polyimide, BCB, PBO, and other material having similar insulating and structural properties.

In FIG. 3l, a portion of insulating layer 230 is removed using an etching process or LDA, similar to FIG. 2h, to form openings extending through insulation-filled vias 228 to adhesive layer 226 and further extending down to expose conductive layer 112.

An electrically conductive material is formed within the openings in insulating layer 230 using PVD, CVD, electrolytic plating, electroless plating process, or other suitable metal deposition process to form conductive vias 232. Conductive vias 232 can be one or more layers of Al, Cu, Sn, Ni, Au, Ag, or other suitable electrically conductive material. Conductive vias 232 extend vertically through insulating layer 230 to adhesive layer 226 and further to electrically connect to conductive layer 112 of electrical components 220a-220b.

An electrically conductive layer 234 is formed over insulating layer 230 using PVD, CVD, electrolytic plating, electroless plating process, or other suitable metal deposition process. Conductive layer 234 can be one or more layers of Al, Cu, Sn, Ni, Au, Ag, or other suitable electrically conductive material. Conductive layer 234 is electrically connected to conductive vias 232 and provides horizontal electrical interconnect across the substrate, such as an RDL.

In FIG. 3m, insulating layer 236 is formed over insulating layer 230 and conductive layer 234 using PVD, CVD, printing, lamination, spin coating, spray coating, sintering or thermal oxidation, similar to FIG. 2j. Insulating layer 236 contains one or more layers of SiO2, Si3N4, SiON, Ta2O5, Al2O3, solder resist, polyimide, BCB, PBO, and other material having similar insulating and structural properties. A portion of insulating layer 236 is removed using an etching process or LDA to form openings extending through insulating layer 236 to conductive layer 234 and conductive vias 232. An electrically conductive material is formed within the openings in insulating layer 236 using PVD, CVD, electrolytic plating, electroless plating process, or other suitable metal deposition process to form conductive vias 238. Conductive vias 238 can be one or more layers of Al, Cu, Sn, Ni, Au, Ag, or other suitable electrically conductive material. Conductive vias 238 extend vertically through insulating layer 236 to electrically connect to conductive layer 234 and conductive vias 232.

An electrically conductive layer 240 is formed over insulating layer 236 and conductive vias 238 using PVD, CVD, electrolytic plating, electroless plating process, or other suitable metal deposition process. Conductive layer 240 can be one or more layers of Al, Cu, Sn, Ni, Au, Ag, or other suitable electrically conductive material. Conductive layer 240 is electrically connected to conductive vias 238 and provides horizontal electrical interconnect across the substrate, such as an RDL. Portions of conductive layers 234 and 240 and conductive vias 232 and 238 can be electrically common or electrically isolated depending on the design and function of electrical components 220a-220b and other electrical components. The combination of conductive layers 234 and 240, conductive vias 232 and 238, and insulating layers 230 and 236 constitute upper interconnect structure 242 formed over surface 210 of substrate 120 and surface 212 of encapsulant 222 and electrical components 220a-220b.

Temporary substrate 224 and adhesive layer 226 are removed by chemical etching, CMP, mechanical peel-off, mechanical grinding, thermal bake, UV light, or wet stripping to expose conductive vias 232 and surface 245 of encapsulant 222.

Lower interconnect and antenna structure 244 is formed over surface 245 of encapsulant 222, similar to FIG. 2k. Lower interconnect and antenna structure 244 includes one or more conductive layers 246 and one or more insulating layers 248. Conductive layers 246 can be one or more layers of Al, Cu, Sn, Ni, Au, Ag, or other suitable electrically conductive material. Conductive layers 246 can be formed using PVD, CVD, electrolytic plating, electroless plating process, or other suitable metal deposition process. Conductive layers 246 provide horizontal electrical interconnect (such as RDL) and vertical electrical interconnect. Portions of conductive layers 246 can be electrically common or electrically isolated depending on the design and function of electrical components 220a and 220b and other electrical components. Insulating layers 248 contain one or more layers of SiO2, Si3N4, SiON, Ta2O5, Al2O3, solder resist, polyimide, BCB, PBO, and other material having similar insulating and structural properties. Insulating layers 248 can be formed using PVD, CVD, printing, lamination, spin coating, spray coating, sintering or thermal oxidation. Insulating layers 248 provide isolation between conductive layers 246. There can be multiple conductive layers like 246 separated by insulating layers 248. Note that conductive vias 232 extend from upper interconnect structure 242 through substrate 204 to electrically connect to conductive layer 246, providing electrical connectivity between upper interconnect structure 242 and lower interconnect and antenna structure 244. Conductive vias 232 provide a short vertical interconnect from embedded electrical components 220a-220b to antennas 247 and surface assembled electrical components 260a-260b, see FIGS. 3n-3p. The combination of upper interconnect structure 242 and lower interconnect and antenna structure 244 provides double-sided electrical connectivity, including double-sided RDL

A conductive layer 247 is formed on surface 250 of lower interconnect and antenna structure 244 and electrically connects to conductive layer 246. Conductive layer 247 includes an array of islands 252 of wound or spiral conductive material suitable to provide transmission and reception of RF signals, i.e., an RF antenna, as shown in FIG. 3n. Alternatively, conductive layer 247 includes an array of islands of wound or spiral conductive material suitable to provide transmission and reception of RF signals, i.e., an RF antenna, similar to FIG. 2m. In yet another embodiment, conductive layer 247 can be formed as a plurality of patch antenna, similar to FIG. 2n. In particular, antenna islands 252 and patch antenna of conductive layer 247 are exposed from surface 250 to improve RF transmission and reception performance and quality.

In another embodiment, a plurality of discrete antenna modules 253a-253d are disposed over surface 245, as shown in FIG. 3o. Patch antenna 254 are formed on a surface of discrete antenna modules 253a-253d opposite surface 245. Patch antenna 254 are electrically connected through substrate 204 to interconnect structure 168 by way of conductive vias 256 and conductive vias 232 and other interconnect structures through substrate 120.

In FIG. 3p, continuing from FIG. 3m, electrical components 260a and 260b are positioned over upper interconnect structure 242 using a pick and place operation, similar to FIGS. 2d-2e. For example, electrical component 260a can be a discrete electrical device, such as a resistor, capacitor, inductor, diode, or transistor. Terminals 264 of electrical component 260a are bonded to electrically connect to conductive layer 240 with conductive paste 266. Electrical component 260b can be similar to semiconductor die 104b from FIG. 1f with active surface 110b oriented toward upper interconnect structure 242. Alternatively, electrical component 260b can include other semiconductor die, semiconductor packages, surface mount devices, discrete electrical devices, or IPDs.

In FIG. 3r, an encapsulant or molding compound 280 is deposited over and around electrical components 260a-260b using a paste printing, compressive molding, transfer molding, liquid encapsulant molding, vacuum lamination, spin coating, or other suitable applicator. Encapsulant 280 can be polymer composite material, such as epoxy resin with filler, epoxy acrylate with filler, or polymer with proper filler. Encapsulant 280 is non-conductive, provides structural support, and environmentally protects the semiconductor device from external elements and contaminants. The combination of embedded substrate 204, electrical components 220a-220b, upper interconnect structure 242, lower interconnect and antenna structure 244, and electrical components 260a-260b constitute AiP module 282. Mask 284 is disposed over connector area 286 of upper interconnect structure 242.

Electrical components 220a-220b and 260a-260b may contain IPDs that are susceptible to or generate EMI, RFI, harmonic distortion, and inter-device interference. For example, the IPDs contained within electrical components 220a-220b and 260a-260b provide the electrical characteristics needed for high-frequency applications, such as resonators, high-pass filters, low-pass filters, band-pass filters, symmetric Hi-Q resonant transformers, and tuning capacitors. In another embodiment, electrical components 220a-220b and 260a-260b contain digital circuits switching at a high frequency, which could interfere with the operation of IPDs in the assembly.

To address EMI, RFI, harmonic distortion, and inter-device interference, electromagnetic shielding material 290 is applied over encapsulant 280 covering semiconductor assembly 282, including side surface 292 of encapsulant 280 and side surface 194 of substrate 204 and mask 284, as shown in FIG. 3r. Electromagnetic shielding material 290 can be one or more layers of Al, Cu, Sn, Ni, Au, Ag, or other suitable conductive material. Alternatively, electromagnetic shielding material 290 can be carbonyl iron, stainless steel, nickel silver, low-carbon steel, silicon-iron steel, foil, conductive resin, carbon-black, aluminum flake, and other metals and composites capable of reducing or inhibiting the effects of EMI, RFI, and other inter-device interference.

In FIG. 3s, a portion of shielding material 290 over mask 284 in connector area 286, as well as the mask, are removed by etching, LDA, or grinding operation, leaving an exposed conductive layer 240 of upper interconnect structure 242. Electrical connector 296 with bump material or conductive paste 298 is disposed over the exposed conductive layer 240. Bumps 298 are brought into contact with the exposed conductive layer 240 and reflowed or cured to make electrical and mechanical interconnection to the conductive layer.

FIG. 3s represents AiP module 300 with an embedded glass substrate 204. Electrical components 220a-220b are disposed within a cavity of the embedded glass substrate. An electrical interconnect structure 242 is formed on one side of the glass substrate and an antenna structure 244 is formed on the opposite side of the glass substrate. Encapsulant can be deposited over electrical components 260a-260b. A shielding layer can be formed to the package. AiP module 300 provides improved performance with low-loss thin-film dielectrics, high-precision interconnects with seamless transitions, and short vertical interconnects from embedded electrical components to antennas and surface assembled components. AiP module 300 has lower form factor with 100-200 mm thick core, providing shrinkage in the Z-direction. Double-side RDL and passive device integration reduces the number of metal layers. AiP module 300 involves lower cost with large-area panel manufacturing and double-side panel-level fabrication and assembly.

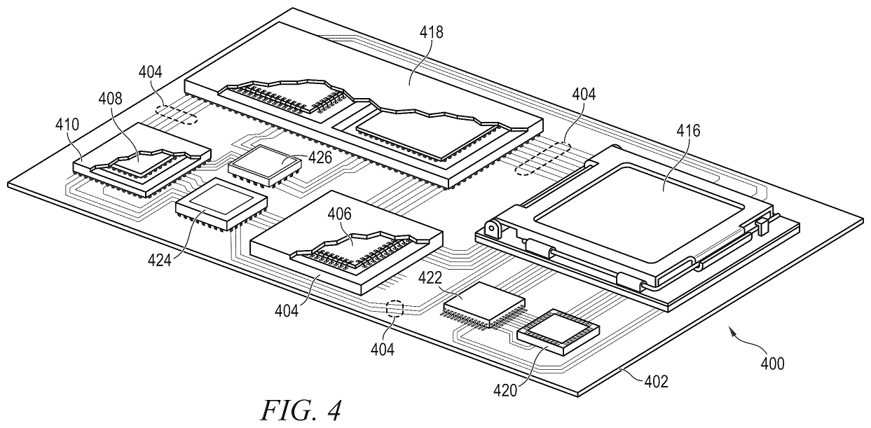

FIG. 4 illustrates electrical device 400 having a chip carrier substrate or PCB 402 with a plurality of semiconductor packages disposed on a surface of PCB 402, including AiP modules 198 and 300. Electrical device 400 can have one type of semiconductor package, or multiple types of semiconductor packages, depending on the application.

Electrical device 400 can be a stand-alone system that uses the semiconductor packages to perform one or more electrical functions. Alternatively, electrical device 400 can be a subcomponent of a larger system. For example, electrical device 400 can be part of a tablet, cellular phone, digital camera, communication system, or other electrical device. Alternatively, electrical device 400 can be a graphics card, network interface card, or other signal processing card that can be inserted into a computer. The semiconductor package can include microprocessors, memories, ASIC, logic circuits, analog circuits, RF circuits, discrete devices, or other semiconductor die or electrical components. Miniaturization and weight reduction are essential for the products to be accepted by the market. The distance between semiconductor devices may be decreased to achieve higher density.

In FIG. 4, PCB 402 provides a general substrate for structural support and electrical interconnect of the semiconductor packages disposed on the PCB. Conductive signal traces 404 are formed over a surface or within layers of PCB 402 using evaporation, electrolytic plating, electroless plating, screen printing, or other suitable metal deposition process. Signal traces 404 provide for electrical communication between each of the semiconductor packages, mounted components, and other external system components. Traces 404 also provide power and ground connections to each of the semiconductor packages.

In some embodiments, a semiconductor device has two packaging levels. First level packaging is a technique for mechanically and electrically attaching the semiconductor die to an intermediate substrate. Second level packaging involves mechanically and electrically attaching the intermediate substrate to the PCB. In other embodiments, a semiconductor device may only have the first level packaging where the die is mechanically and electrically disposed directly on the PCB.

For the purpose of illustration, several types of first level packaging, including bond wire package 406 and flipchip 408, are shown on PCB 402. Additionally, several types of second level packaging, including ball grid array (BGA) 410, bump chip carrier (BCC) 412, land grid array (LGA) 416, multi-chip module (MCM) or SIP module 418, quad flat non-leaded package (QFN) 420, quad flat package 422, embedded wafer level ball grid array (eWLB) 424, and wafer level chip scale package (WLCSP) 426 are shown disposed on PCB 402. In one embodiment, eWLB 424 is a fan-out wafer level package (Fo-WLP) and WLCSP 426 is a fan-in wafer level package (Fi-WLP). Depending upon the system requirements, any combination of semiconductor packages, configured with any combination of first and second level packaging styles, as well as other electrical components, can be connected to PCB 402. In some embodiments, electrical device 400 includes a single attached semiconductor package, while other embodiments call for multiple interconnected packages. By combining one or more semiconductor packages over a single substrate, manufacturers can incorporate pre-made components into electrical devices and systems. Because the semiconductor packages include sophisticated functionality, electrical devices can be manufactured using less expensive components and a streamlined manufacturing process. The resulting devices are less likely to fail and less expensive to manufacture resulting in a lower cost for consumers.

While one or more embodiments of the present invention have been illustrated in detail, the skilled artisan will appreciate that modifications and adaptations to those embodiments may be made without departing from the scope of the present invention as set forth in the following claims.

What is claimed:

1. A semiconductor device, comprising:
a substrate;
a first electrical component disposed within a cavity in the substrate;
an interconnect structure formed over a first surface of the substrate and the first electrical component; and
an antenna structure formed over a second surface of the substrate opposite the first surface of the substrate.

2. The semiconductor device of claim 1, wherein the substrate includes glass.

3. The semiconductor device of claim 1, further including a conductive via formed through the substrate between the interconnect substrate and antenna structure.

4. The semiconductor device of claim 1, further including a second electrical component disposed over the interconnect structure.

5. The semiconductor device of claim 4, further including an encapsulant deposited over the second electrical component.

6. The semiconductor device of claim 5, further including a shielding layer disposed over and around the encapsulant.

7. A semiconductor device, comprising:
a substrate;
a first electrical component disposed over the substrate;
an interconnect structure formed over a first surface of the substrate; and
an antenna structure formed over a second surface of the substrate opposite the first surface of the substrate.

8. The semiconductor device of claim 7, wherein the substrate includes glass.

9. The semiconductor device of claim 7, further including a conductive via formed through the substrate between the interconnect substrate and antenna structure.

10. The semiconductor device of claim 7, further including a second electrical component disposed over the interconnect structure.

11. The semiconductor device of claim 10, further including an encapsulant deposited over the second electrical component.

12. The semiconductor device of claim 11, further including a shielding layer disposed over and around the encapsulant.

13. The semiconductor device of claim 7, further including an electrical connector disposed over the interconnect structure.

14. A method of making a semiconductor device, comprising:
providing a substrate;
disposing a first electrical component within a cavity in the substrate;
forming an interconnect structure over a first surface of the substrate and the first electrical component; and
forming an antenna structure over a second surface of the substrate opposite the first surface of the substrate.

15. The method of claim 14, wherein the substrate includes glass.

16. The method of claim 14, further including forming a conductive via through the substrate between the interconnect substrate and antenna structure.

17. The method of claim 14, further including disposing a second electrical component over the interconnect structure.

18. The method of claim 17, further including depositing an encapsulant over the second electrical component.

19. The method of claim 18, further including disposing a shielding layer over and around the encapsulant.

20. A method of making a semiconductor device, comprising:
providing a substrate;
disposing a first electrical component over the substrate;
forming an interconnect structure over a first surface of the substrate; and
forming an antenna structure over a second surface of the substrate opposite the first surface of the substrate.

21. The method of claim 20, wherein the substrate includes glass.

22. The method of claim 20, further including forming a conductive via through the substrate between the interconnect substrate and antenna structure.

23. The method of claim 20, further including disposing a second electrical component over the interconnect structure.

24. The method of claim 23, further including depositing an encapsulant over the second electrical component.

25. The method of claim 24, further including disposing a shielding layer over and around the encapsulant.
